(19) United States
(12) Patent Application Publication
(10) Pub. No.: US 2010/0052649 A1
(43) Pub. Date: Mar. 4, 2010

(54) DEVICE FOR READING ELECTRONIC CHARGES AND DETECTOR COMPRISING SUCH DEVICES

(75) Inventor: Michel ZECRI, Bevenais (FR)

Correspondence Address: BURR & BROWN, PO BOX 7068, SYRACUSE, NY, 13261-7068, US

(73) Assignee: Societe Francaise De Detecteurs Infrarouges- Sofradir, Chatenay Malabry (FR)

(21) Appl. No.: 12/510,472

(22) Filed: Jul. 28, 2009

(30) Foreign Application Priority Data
Sep. 2, 2008 (FR) 08.55884

(51) Int. Cl. G01R 19/00

(52) U.S. Cl. 324/76.11

(57) ABSTRACT

The invention relates to a device for reading electronic charges, comprising an input for receiving the electronic charges, at least one capacitor for storing the electronic charges and at least one circuit based on MOS transistors, whereof the maximum operating voltage determines the maximum voltage at the terminals of the at least one capacitor (20, 38), and wherein the or each MOS transistor-based circuit is constituted by cascode-mounted transistors.

### FIELD OF THE INVENTION

The present invention relates to the field of the reading of electronic charges created for example in elementary photo-detectors of a detector, particularly photodiodes.

### PRIOR ART

The use of elementary photo-detectors, and particularly photodiodes, in detecting electromagnetic radiation, is known. The electromagnetic radiation incident upon a photodiode does indeed create electronic charges therein. Said charges are usually collected and accumulated in a storage capacity so that they can be read at a later time.

FIG. 1 shows a circuit for reading 10 the electrical charges created in a photodiode 12 of a matrix detector under the effect of “ER” infrared radiation incident thereupon. The read circuit 10 conventionally comprises an input stage 14 for storing the charges created in the photodiode 12, and a stage for reading 16 the stored charges.

The input stage 12 comprises an injection n channel MOS transistor 18 and a storage capacitor 20. The injection transistor source 18 is connected to a terminal 22 of the photodiode 12, the second terminal 24 of the photodiode 12 being further connected to a constant potential, such as the mass for example. As is known per se, the function of the injection transistor 18 is to polarize the photodiode 12 and to transfer the charges created therein into the storage capacitor 20, which is connected by one terminal 26 to the drain of the transistor 18 and by the other terminal 28 to the mass.

The input stage 12 also comprises an initialization p channel MOS transistor 29, whereof the drain is connected to the terminal 26 of the storage capacitor 20, and whereof the source is connected to a constant potential “V+” equal to Vdda−Vsat, where “Vdda” is a constant pre-set supply voltage of the read circuit 10 and “Vsat” is the saturation voltage of the transistor 29. As is known, the function of the initialization transistor 29 is to discharge the storage capacitor 20 before a charge accumulation therein.

The read stage 16 comprises a switch 30 connected to the terminal 26 of the storage capacitor 20, formed for example of an n channel MOS transistor 32 and a p channel MOS transistor 34, a read capacitor 36 connected by one terminal 38 to the switch 30 and by the other terminal 40 to the mass, an initialization p channel MOS transistor 42, whereof the source is connected to the constant potential “V+”, and whereof the drain is connected to the terminal 38 of the read capacitor 36, and a charge pre-amplifier 44.

The pre-amplifier 44 comprises for example an operational amplifier 46, a first n channel MOS transistor 48, whereof the gate is connected to the terminal 38 of the read capacitor 36, and whereof the drain is connected to a first input terminal of the amplifier 46, and a second n channel MOS transistor 50 whereof the drain is connected to the source of the first transistor and whereof the source is connected to the second input terminal of the amplifier 46, and whereof the gate receives an addressing signal “@” corresponding to the matrix detector column to which the photodiode 12 belongs.

In operation, the photodiode 12 is polarized by the injection transistor 18 and the charges created in said photodiode are stored in the capacitor 20, which has been previously discharged by means of the initialization transistor 29, the switch 30 furthermore being on.

Once the pre-set exposure time has elapsed, the switch 30 is turned off. The charges stored in the capacitor 20 are then transferred to the read capacitor 36, previously initialized by means of the transistor 42, and then amplified by the pre-amplifier 44 so as to be delivered on a bus for example.

The total electrical charge Q that can be stored in each of the storage and read capacitors 20, 36 is determined in accordance with the relation Q=CV, where C is the capacity of the capacitor and V the voltage at the terminals thereof, in this case substantially equal to “Vdda−Vsat”.

To increase the total storage charge Q, in order for example to increase detector dynamics or improve the signal-to-noise ratio thereof, it is therefore necessary to increase the capacity C of the capacitors 20, 36 and/or the voltage V at the terminals thereof.

Now, as is known per se, an electronic charge read circuit is associated with each photodiode of a matrix detector, so that said circuit is usually formed over a reduced surface, in particular for reasons of compactness. Since the capacity C of a capacitor is dependent upon the surface allocated thereto, increasing the capacity runs counter to the compactness criterion.

Furthermore, increasing the voltage at the terminals of the capacitors involves subjecting the transistors 18, 26, 42, 48, 50 to higher voltages. In fact, transistors are usually designed to operate under a pre-set maximum voltage, in order to guarantee the reliability of these components. To increase the voltage at the terminals of the capacitors in order to increase the total storable charge it is therefore essential for the MOS transistors 18, 26, 42, 48, 50 to be subjected to voltage constraints that reduce their life span, and may even destroy them. In fact, the maximum operating voltage of the transistors 18, 26, 42, 48, 50 determines the maximum voltage that can be applied at the terminals of the capacitors 20, 36.

### DISCLOSURE OF THE INVENTION

The purpose of the present invention is to resolve the aforementioned problem by proposing an electrical charge read device that is straightforward and compact in design, and that allows the total charge that can be stored in the capacitors to be increased without subjecting the transistors to massive constraints in terms of voltage.

To this end, the object of the invention is a device for reading electronic charges, comprising an input for receiving the electronic charges, at least one capacitor for storing the electronic charges and at least one MOS transistor-based circuit whereof the maximum operating voltage determines the maximum voltage at the terminals of at least one capacitor.

According to the invention, the or each MOS transistor-based circuit is constituted by cascode-mounted transistors.

As is known per se, “cascode-mounted” transistors are taken to mean transistors connected in series, with the drain of one transistor being connected to the source of another transistor.

In other words, the MOS transistors of the electrical charge read device, whereof the operating voltage restricts the voltage that can be applied at the terminals of the capacitors, are cascode-mounted with at least one other MOS transistor.

Each transistor thus sees a lower voltage at its terminals. For example, for an assembly of two cascode-mounted transistors, each of the transistors sees half the total voltage applied to the assembly. Since the maximum operating voltage of such an assembly is greater than the maximum voltage of a single transistor, it is possible to increase the voltage at the terminals of the capacitors without subjecting the transistors to voltage constraints that may cause damage.

The cascode-mounting arrangement of the transistors is thus used to lower the voltage at the terminals of each transistor.

According to one particular inventive embodiment, the MOS transistor-based circuit is an injection circuit for polarizing a photo-detector connected to the input and for transferring the electronic charges received at the input to the at least one capacitor, said injection circuit comprising two cascode-mounted MOS transistors.

According to one particular inventive embodiment, the MOS transistor-based circuit is an initialization circuit of at least one capacitor, said initialization circuit comprising two cascode-mounted MOS transistors.

According to one particular inventive embodiment, the MOS transistor-based circuit is a charge pre-amplifier comprising an input stage formed of cascode-mounted MOS transistors.

A further object of the invention is a detector comprising a plurality of elementary photo-detectors capable of creating electronic charges under the effect of incident radiation, the detector comprising, associated with each of the elementary photo-detectors, a device in accordance with the one previously described for the reading of charges created by the photo-detector.

In other words, the present invention can be used to advantage in detectors that usually comprise circuits for reading electronic charges created in their elementary photo-detectors. Increasing the voltage at the capacitor terminals allows in particular detector dynamics, and the signal-to-noise ratio thereof, to be improved while preserving a long transistor life cycle.

### BRIEF DESCRIPTION OF THE FIGURES

The invention will be better understood from reading the following description, given solely by way of example, and produced in relation to the appended drawings wherein identical references denote identical or similar elements, and wherein:

FIG. 1 is a schematic view of a prior art read circuit associated with a photodiode, said circuit having been described in the introduction; and

FIG. 2 is a schematic view of a read circuit according to the invention.

### DETAILED DESCRIPTION OF THE INVENTION

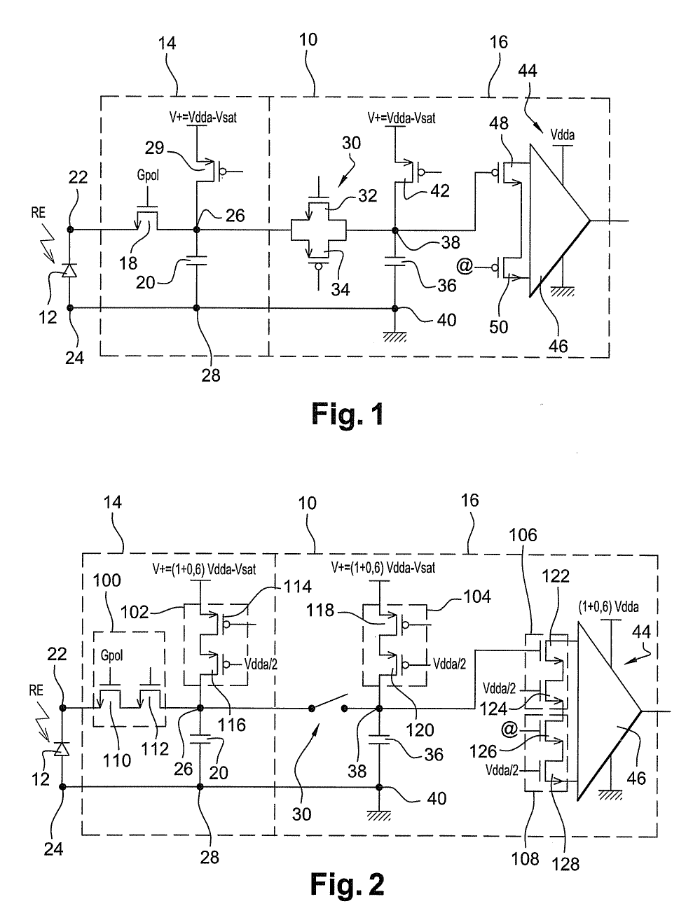

FIG. 2 shows the inventive principle applied to the prior art read circuit described in relation to FIG. 1.

According to the invention, each MOS transistor 18, 29, 42, 48 and 50 in FIG. 1, whereof the operating voltage restricts the voltage that can be applied to the terminals of the capacitors 20 and 36, is replaced by a corresponding assembly 100-108 respectively constituted by two cascode-mounted MOS transistors 110-128 of the same type, each of the assemblies 100-108 fulfilling the same function as the transistor it replaces.

Because of the cascode-mounting arrangement, each of the transistors 110, 112 of the assembly 100 forming the injection circuit, thus sees half the voltage applied between the terminals 22 and 26. Likewise, each of the transistors 114, 116 of the assembly 102 forming initialization circuit of the storage capacitor 20, sees half the voltage between the terminal 26 and the constant potential “V+”.

Similarly, the transistors 118, 120, 122, 124, 126, 128 see half the voltage applied at the terminals of their respective assembly 104, 106, 108.

It is thus possible to increase the supply voltage “Vdda” of the read circuit 10, and consequently the voltage applied at the terminals of the capacitors 20 and 36 without the resulting voltage at the terminals of the transistors 110-128 exceeding the maximum operating voltage thereof. For example, an increase of 100 percent in the supply voltage “Vdda” is possible.

By doing this, because of the increase in voltage at the capacitor terminals, it becomes possible to increase the charge storage capacity in each of them, by applying the relation Q=CV.

Quite obviously, the read circuits described in relation to FIGS. 1 and 2 are given by way of illustration. It will obviously be understood that the present invention applies to any type of electrical charge read device that includes capacitors and MOS transistors, whereof the operating voltages are restricted, and this is true irrespective of the mode of operation of the read circuit, and particularly “IWR” (Integrate-While-Read) and “ITR” (Integrate-Then-Read) operating modes.

Likewise, the invention may be applied solely at the input stage 14 of the read circuit 10.

Likewise, it is possible to use more than two cascode-mounted transistors for each assembly depending on the specific needs of each application.

1. A device for reading electronic charges, comprising an input for receiving the electronic charges, at least one capacitor for storing the electronic charges, and at least one circuit based on MOS transistors, whereof the maximum operating voltage determines the maximum voltage at the terminals of the at least one capacitor, wherein the or each MOS transistor-based circuit is constituted by cascode-mounted transistors.

2. A device as claimed in claim 1, wherein the MOS transistor-based circuit is an injection circuit for polarizing a photo-detector connected to the input and for transferring the electronic charges received at the input to the at least one capacitor, said injection circuit comprising two cascode-mounted MOS transistors.

3. A device as claimed in claim 1, wherein the MOS transistor-based circuit is an initialization circuit of the at least one capacitor, said initialization circuit comprising two cascode-mounted MOS transistors.

4. A device as claimed in claim 1, wherein the MOS transistor-based circuit is a charge pre-amplifier comprising an input stage formed of cascode-mounted MOS transistors.

5. A detector comprising a plurality of elementary photo-detectors capable of creating electronic charges under the effect of incident radiation, the detector comprising, associated with each of the photo-detectors, a device in accordance with any one of previous claims for reading the charges created by the photo-detector.
